(19) United States
(12) Patent Application Publication
(10) Pub. No.: US 2012/0083128 A1
(43) Pub. Date: Apr. 5, 2012

(54) METHOD FOR ETCHING HIGH-ASPECT-RATIO FEATURES

(75) Inventors: Yung-jr Hung, Taipei City (TW); San-liang Lee, Taipei City (TW)

(73) Assignee: National Taiwan University of Science and Technology, Taipei City (TW)

(21) Appl. No.: 13/079,790

(22) Filed: Apr. 4, 2011

(30) Foreign Application Priority Data
Oct. 5, 2010 (TW) 099133879

(51) Int. Cl. H01L 21/3065

(52) U.S. Cl. 438/711; 257/E21.218; 438/712

(57) ABSTRACT

A method for etching high-aspect-ratio features is disclosed. The method is applicable in forming a nanoscale deep trench having a smooth and angle-adjustable sidewall. The method includes: forming a patterned photoresist layer on a surface of a silicon substrate for exposing a part of the silicon substrate; and supplying a process gas simultaneously containing sulfur hexafluoride (SF₆) and fluorinated carbon composition into a chamber in which the substrate in positioned for carrying out a deep reactive ion etching operation to etch the part of the silicon substrate for forming the deep trench. The method forms a nanoscale deep trench with a high silicon-to-photoresist etching selectivity.

This invention is partly disclosed in an Journal Paper published in Mater. Res. Soc. Symp. Proc. Vol. 1258© 2010 Materials Research Society, entitled “Realization of silicon nanopillar arrays with controllable sidewall profiles by holography lithography and a novel single-step deep reactive ion etching” completed by Yung-Jr Hung, and published on Apr. 5, 2010.

### CLAIM OF PRIORITY

This application claims priority to Taiwanese Patent Application No. 099133879 filed on Oct. 5, 2010.

### TECHNICAL FIELD OF THE INVENTION

The present invention relates to a semiconductor processing technology, and more particularly to a method for etching high-aspect-ratio features in semiconductor devices.

### BACKGROUND OF THE INVENTION

In an MEMS (Micro Electro Mechanical System) manufacturing process, a deep silicon etching technology is utilized to fabricate micro components with a high aspect ratio. The deep silicon etching which has been widely used, such as U.S. Pat. Nos. 5,498,312 and 5,501,893, is an anisotropic deep silicon etching process developed by the Robert Bosch company of Germany. The process is generally known as Bosch etching technology. The Bosch etching technology is a process which utilizes a plasma source having an silicon etching reaction and another plasma source having an ability to form a polymeric passivation layer, and the two plasma sources are repeatedly alternate to achieve the manufacturing procedure requirements of high selectivity, high anisotropy, high etching depth, and high aspect ratio.

Referring to FIG. 1, which is a schematic cross-sectional view illustrating an etched sample by the conventional Bosch etching technology, according to Bosch etching, etching and deposition are alternately and periodically performed so that a periodic ripple structure or “scalloping” of the sidewalls is formed after etching a sample 12 by the Bosch etching technology. The typical size of each ripple structure is in the scale of several hundred nanometers. As to the most MEMS components, their scales are often above tens or hundreds of microns, so that the scalloping of the sidewalls 32 has little effect on the MEMS components.

However, if the Bosch etching technology is applied to etch sub-micron or nanoscale structures, the scalloping of the sidewalls 32 will greatly affected the resultant profiles.

Thus, in the technology of fabricating sub-micron or nanoscale structures in a silicon substrate, a deep silicon etching technology of a single step is often utilized. For instance, a gas mixture of “chlorine (Cl₂), hydrogen bromide (HBr), and nitrogen (N₂)” or “sulfur hexafluoride (SF₆), oxygen (O₂), and hydrogen bromide (HBr)” is utilized to perform a reactive ion etching (RIE) in integrated circuits. However, as to a photoresist layer and a silicon substrate, the single-step etching technology using the above-mentioned gas mixture has no enough etching selectivity. Therefore, an additional patterned hard mask, such as silicon oxide, silicon nitride or metal layer, has to be formed on the silicon substrate for increasing the etching selectivity in order to fabricate high-aspect-ratio etched trenches. This increases production complexity, cost and time.

### SUMMARY OF THE INVENTION

An objective of the present invention is to provide a method for etching high-aspect-ratio features, which helps solving the problems in connection with the scalloping of sidewall and the requirement of the additional hard mask mentioned above.

To achieve the foregoing objective, according to an aspect of the present invention, a method applicable in etching high-aspect-ratio features in fabrication of a nanoscale deep trench having a smooth and angle-adjustable sidewall is provided. The method comprises the steps of forming a patterned photoresist layer on a surface of a silicon substrate for exposing a part of the silicon substrate; and supplying a process gas simultaneously containing sulfur hexafluoride (SF₆) and fluorinated carbon composition into a chamber in which the substrate is positioned for carrying out a deep reactive ion etching to etch the exposed part of the silicon substrate for forming the deep trench.

In a preferred embodiment of the present invention, the step of supplying the process gas further comprises supplying argon into the chamber. In addition, a sidewall angle of the deep trench is controlled by a flow ratio between SF₆ and the fluorinated carbon composition. In an embodiment, the fluorinated carbon composition comprises octafluorocyclobutane (C₄F₈).

In a preferred embodiment of the present invention, a sidewall angle of the deep trench is controlled by an etching parameter, such as a chamber pressure or a DC bias power of the deep reactive ion etching. It is noted that an etching selectivity of the silicon substrate with respect to the patterned photoresist layer is set between 10 and 20. The etching selectivity can be controlled through controlling a DC bias power. In addition, an aspect ratio of the deep trench is between 2:1 and 50:1. A width of the deep trench is between 50 nanometers and 2000 nanometers.

In accordance with a preferred embodiment of the present invention, the method has the advantages of the Bosch etching technology, such as high etching selectivity, anisotropic etching behavior, high etching rate and high aspect ratio, but shows no scalloping on the sidewall of the deep trench, so that the method of the present invention is capable of forming a deep trench of nanoscale. In addition, compared to the conventional single-step etching technology, because the method of the present invention has a high etching selectivity over the photoresist, there will be of no need to make masks of silicon oxide, silicon nitride, or metal. Moreover, the method provides a way to control the sidewall angle.

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 is a schematic cross-sectional view illustrating an etched sample by a conventional Bosch etching technology;

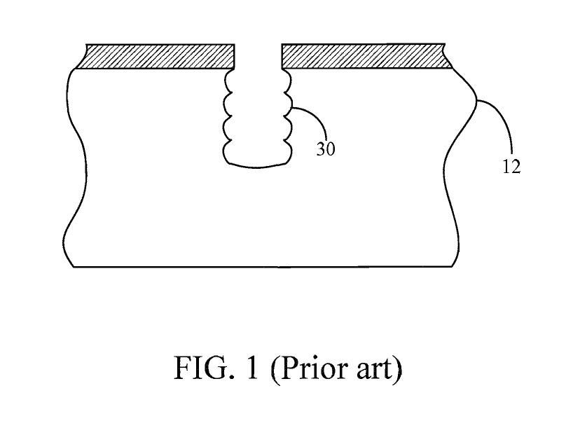

FIG. 2 is a flow chart illustrating a method for etching high-aspect-ratio features according to a preferred embodiment of the present invention; and

FIGS. 3a and 3b are schematic cross-sectional views illustrating steps of the method according to the preferred embodiment of the present invention.

### DETAILED DESCRIPTION OF THE INVENTION

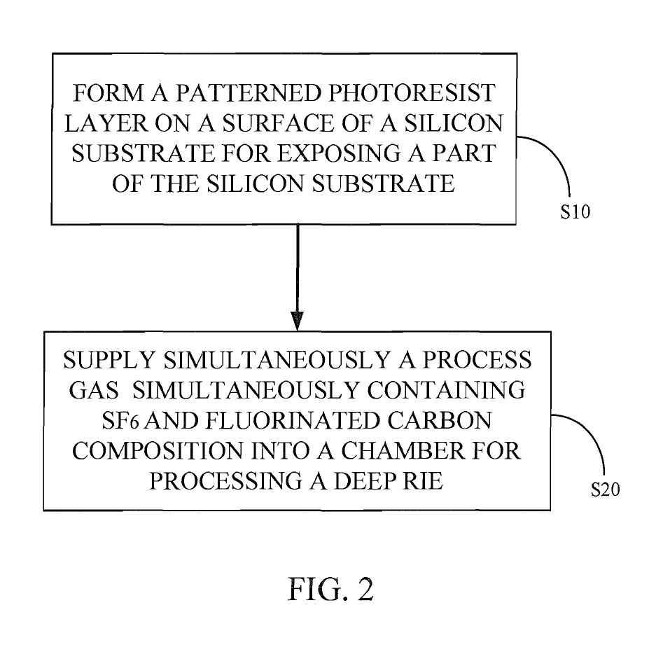

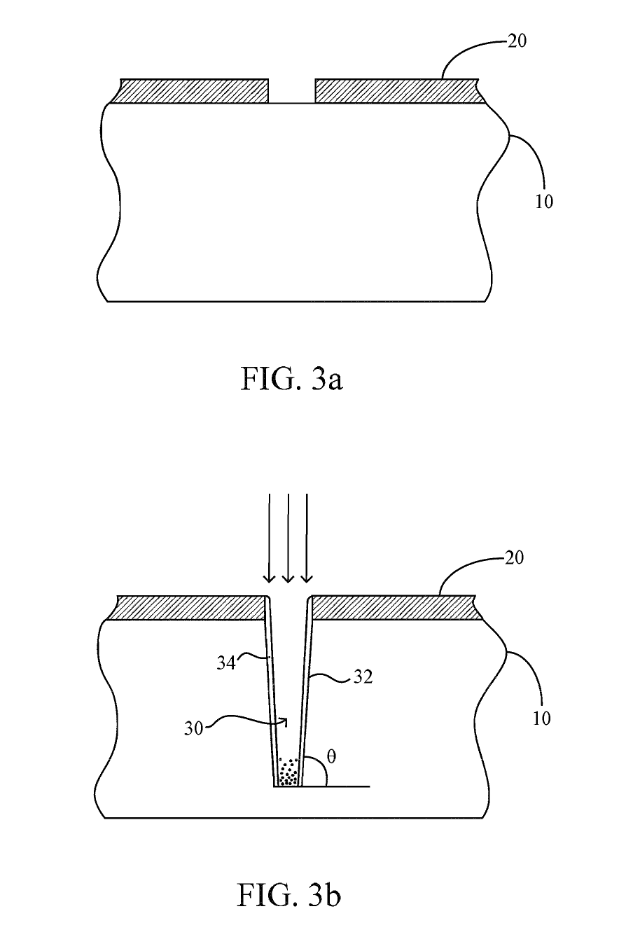

The following will explain a method for etching a high-aspect-ratio feature according to a preferred embodiment of the present invention in detail with the attached drawings. Referring to FIGS. 2, 3a, and 3b, FIG. 2 is a flow chart illustrating a method for etching a high-aspect-ratio feature according to the preferred embodiment of the present invention. FIGS. 3a and 3b are schematic cross-sectional views illustrating steps of the method according to the preferred embodiment of the present invention. The etching method is utilized to fabricate a nanoscale deep trench 30 on a silicon substrate 10, and the deep trench 30 has a smooth sidewall 32 with a controllable sidewall angle θ.

Referring to FIGS. 2 and 3a, at step S10, a patterned photoresist layer 20 is formed on a surface of the silicon substrate 10 for exposing a part of the silicon substrate 10. The silicon substrate 10 is a substrate which has a silicon layer on a surface thereof, such as a silicon base or a silicon-on-insulator (SOI), and in the following description, a silicon base is taken as an example for explanation purposes. The patterned photoresist layer 20 is formed on the silicon substrate 10 by adopting a semiconductor process so that a part of the silicon substrate 10 is exposed. The photoresist layer 20 is made of for example a polymer. The semiconductor process adopted to form the patterned photoresist layer 20 can be a process that is familiar to those skilled in the art, such as a mask process, a laser direct writing, a holography technique, and the likes, and further details are not necessary herein. The patterned photoresist layer 20 serves as an etching mask along with step S20 being subsequently performed to etch the exposed part of the silicon substrate 10.

At step S20, referring to FIGS. 2 and 3b, a process gas, which simultaneously contains sulfur hexafluoride (SF₆) and a fluorinated carbon composition, is supplied into a chamber (not shown) for performing a deep reactive ion etching (RIE) on the silicon substrate 10 so that the exposed part of the silicon substrate 10 is etched to form a deep trench 30. Specifically, the step of the deep reactive ion etching can be performed by a conventional Bosch etching machine, such as inductively coupled plasma (ICP) system. The ICP employs an induced magnetic field generated from a high frequency induction coil to increase the collision probability of the gas in the chamber for making gas dissociation. Furthermore, sufficient energy is raised so as to generate reactive ion plasma (shown as arrows) for etching the part of the silicon substrate 10 that is not covered and protected by the photoresist layer 20.

The ICP system comprises a chamber, a vacuum system, a gas flow control system, and an etching control system (not shown). In the preferred embodiment of the present invention, the silicon substrate 10 is disposed in the chamber, and the vacuum system is utilized to evacuate the chamber. In addition, the gas flow control system controls the flow rates of both sulfur hexafluoride (SF₆) and fluorinated carbon composition. The gas flow control system is combined with or coupled to a computer for controlling an etching parameter of the etching operation. The etching parameter used in the present invention includes for example chamber pressure, DC bias power, ICP source power, and etching time.

Referring to FIGS. 3a and 3b, the above-mentioned process gas is depicted as particles (small dots in FIG. 3b) for easy recognized. Six fluorine atoms can be dissociated from the SF₆, and the fluorine atoms react with silicon (Si) on the silicon substrate 10 spontaneously to form volatile silicon tetrafluoride (SiF₄). Meanwhile, the fluorinated carbon composition is dissociated mainly as CF₂, which deposits on the sidewall 32 to form a sidewall passivation layer 34. The sidewall passivation layer 34 reduces the reaction between the fluorine atoms and the sidewall 32 and thus protects the sidewall 32. In addition, since the deposition rate of the CF₂ deposited on the photoresist layer 20 is higher than that deposited on the silicon substrate, a higher etching selectivity of the silicon substrate is obtained over the photoresist layer 20. More specifically, the fluorinated carbon composition preferably is octafluorocyclobutane C₄F₈, but the fluorinated carbon composition is not limited to be the octafluorocyclobutane C₄F₈ in the present invention. The fluorinated carbon composition also can be perfluorocarbon such as C₄F₆ and C₄F₁₀. Argon (Ar) gas can also be supplied into the chamber at the same time in addition to the above-mentioned sulfur hexafluoride (SF₆) and the fluorinated carbon composition according to the present invention. The Argon gas is not involved in the actual chemical reaction, and only helps stabilizing the above-mentioned dissociated gas for making the etching effect more uniform.

Therefore, the SF₆ gas is utilized for reaction with silicon to generate the desired etching effect, and the fluorinated carbon composition is utilized to form, through deposition, a passivation layer on the silicon substrate 10. However, the dissociated gas, besides being involved in the chemical reaction, shows a directional ion bombardment effect toward the silicon substrate 10, whereby the dissociated gas can continuously etch the silicon substrate 10 to a deep location. The passivation layer, which is formed by the dissociation of the fluorinated carbon composition, is present on the sidewall 32 and thus, the sidewall 32 is not subject to the ion bombardment directly, thereby inhibiting the lateral etching, and consequently, a deep trench 30 with a high-aspect-ratio can be obtained. Because the etching caused by the sulfur hexafluoride SF₆ and the deposition of the fluorinated carbon composition are simultaneously performed, scalloping of sidewall will not be formed.

The etching method of the preferred embodiment of the present invention is a single step etching, that is, the two gases are supplied simultaneously. Thus, a sidewall angle of the deep trench 30 can be controlled by a proportion between SF₆ and the fluorinated carbon composition. For example, if the SF₆ flow rate is made greater than the flow rate of the fluorinated carbon composition, the etching is stronger and the sidewall protection is weaker. Thus, the sidewall angle θ becomes large. If the angle θ is greater than 90 degrees, then the deep trench 30 may get an undercut configuration at the bottom thereof. Similarly, if the flow rate of SF₆ is made less than that of the fluorinated carbon composition, the etching gets weaker and the sidewall protection is stronger. Thus, the sidewall angle θ becomes small. If the angle θ is smaller than 90 degrees (as shown in FIG. 2b), then the deep trench 30 so formed gets narrower at the bottom thereof.

Specifically, in an example, the flow rates of SF₆, C₄F₈ and Ar are respectively set to 28, 52 and 20 standard cubic centimeters per minute (sccm), and the chamber pressure is 19 mTorr and ICP and DC bias powers are respectively 850 and 9 watts. The sidewall angle θ obtained is substantially a vertical angle (90 degrees). It is noted here that the etching selectivity of the silicon substrate 10 with respect to the patterned photoresist layer 20 is between 10 and 20, preferably. With the above-mentioned parameters, the etching selectivity is 16.52. In addition, an aspect ratio of the deep trench is between 2:1 and 50:1, preferably. Moreover, since the sidewall 30 is substantially flat, the deep trench 30 can be of a width nanoscale (between 50 nm to 2000 nm) without scalloping of the sidewall.

On the other hand, the ion bombardment is affected by the DC bias power, so that the etching selectivity can be controlled by the DC bias power. Thus, if the DC bias power is increased, the effect of ion bombardment toward the surface of the silicon substrate 10 increases and the ion bombardment toward the sidewall 32 is less significant. Therefore, the etching rate of the silicon substrate 10 in the vertical direction and the etching rate of the photoresist layer 20 increase, so that the etching selectivity decreases.

Further, the sidewall angle of the deep trench 30 is controllable by etching parameters of the deep reactive ion etching operation, such as chamber pressure and DC bias power. Since the chamber pressure relates to a total quantity of SF₆ and the fluorinated carbon composition, the proportions of sulfur hexafluoride SF₆ and the fluorinated carbon composition change as soon as the chamber pressure changes, thereby rendering the sidewall angle θ controlled as desired. Taking the flow rates of SF₆ and C₄F₈ as an example, the sidewall 32 becomes vertical when the flow rates of SF₆ and C₄F₈ fare 28 sccm and 52 sccm respectively. If the chamber pressure increases which equally increases the flow rates of SF₆ and C₄F₈, thereby making the proportion of sulfur hexafluoride (SF₆) increases, the sidewall angle θ will get greater than 90 degrees, and then the deep trench 30 formed will have an undercut which is wider at the bottom of trench.

In summary, the method according to the present invention has the advantages of the Bosch etching technology, such as high etching selectivity, anisotropic etching behavior, high etching rate, and high aspect ratio, but shows no scalloping on the sidewall 32 of the deep trench 30. Thus, the present invention is capable of forming a nanostructure. In addition, compared to the conventional single-step etching technology, because the method of the present invention has a high etching selectivity over the photoresist, there will be of no need to make masks of silicon oxide, silicon nitride, or metal. Moreover, the method provides a way to control the sidewall angle of the deep trench 30 through controlling one or more etching parameters.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A method for etching high-aspect-ratio feature in fabrication of a nanoscale deep trench having a smooth and angle-adjustable sidewall, the method comprising the steps of:
forming a patterned photoresist layer on a surface of a silicon substrate for exposing a part of the silicon substrate; and
supplying a process gas simultaneously containing sulfur hexafluoride (SF₆) and fluorinated carbon composition into a chamber in which the silicon substrate is positioned to perform a deep reactive ion etching operation to etch the exposed part of the silicon substrate for forming the deep trench.

2. The method of claim 1, wherein the steps of supplying the process gas further comprises supplying argon into the chamber.

3. The method of claim 1, wherein a sidewall angle of the deep trench is controlled by a proportion between SF₆ and the fluorinated carbon composition.

4. The method of claim 1, wherein the fluorinated carbon composition comprises octafluorocyclobutane (C₄F₈).

5. The method of claim 1, wherein a sidewall angle of the deep trench is controlled by an etching parameter of the deep reactive ion etching.

6. The method of claim 5, wherein the etching parameter comprises a chamber pressure.

7. The method of claim 1, wherein an etching selectivity of the silicon substrate with respect to the patterned photoresist layer is set between 10 and 20.

8. The method of claim 7, wherein the etching selectivity is controlled through controlling a DC bias power.

9. The method of claim 1, wherein an aspect ratio of the deep trench is between 2:1 and 50:1.

10. The method of claim 1, wherein a width of the deep trench is between 50 nanometers and 2000 nanometers.
